(19) United States
(12) Patent Application Publication
(10) Pub. No.: US 2025/0194073 A1
(43) Pub. Date: Jun. 12, 2025

(54) SEMICONDUCTOR DEVICE AND METHOD OF MANUFACTURING THE SAME

(71) Applicant: SAMSUNG ELECTRONICS CO., LTD., SUWON-SI (KR)

(72) Inventors: Yunjae LEE, Suwon-si (KR); Yurim KIM, Suwon-si (KR); Seunghee LEE, Suwon-si (KR); Jihyun KHO, Suwon-si (KR); Minsung KIM, Suwon-si (KR); Jisoo IM, Suwon-si (KR); Dongwan KIM, Suwon-si (KR)

(21) Appl. No.: 18/959,759

(22) Filed: Nov. 26, 2024

(30) Foreign Application Priority Data
Dec. 8, 2023 (KR) 10-2023-0178053

(51) Int. Cl. H10B 12/00

(52) U.S. Cl. CPC H10B 12/05; H10B 12/315

(57) ABSTRACT

A method of manufacturing a semiconductor device includes forming a bit line on a substrate. A first mold layer is formed on the bit line and includes mold openings. A channel layer is formed in the mold openings and covers the bit line and the first mold layer. A partial area of the channel layer is processed with a neutral beam to change an oxygen vacancy concentration of the partial area. A second mold layer is formed covering the channel layer. The second mold layer and a portion of the channel layer covering an upper surface of the first mold layer are removed. A gate insulating layer covering a sidewall of the channel layer and a word line covering a sidewall of the gate insulating layer are formed. A plurality of insulating patterns is formed filling the mold openings. A contact layer connected to the channel layer is formed.

### CROSS-REFERENCE TO RELATED APPLICATION

This application claims priority under 35 U.S.C. § 119 to Korean Patent Application No. 10-2023-0178053, filed on Dec. 8, 2023 in the Korean Intellectual Property Office, the disclosure of which is incorporated by reference in its entirety herein.

### 1. TECHNICAL FIELD

The present inventive concept relates to a semiconductor device and a method of manufacturing the same, and more particularly, to a semiconductor device including a channel structure and a method of manufacturing the semiconductor device.

### 2. DISCUSSION OF RELATED ART

The down-scaling of semiconductor devices has rapidly progressed along with the development of electronics technology. A transistor with a channel layer containing an oxide semiconductor material has been proposed to reduce leakage current through a channel region.

When a channel layer containing an oxide semiconductor material is deposited, intermolecular bonds within the oxide semiconductor material break which causes oxygen vacancy. The characteristics of the transistor may be degraded by the oxygen vacancy.

### SUMMARY

Embodiments of the present inventive concept provides a semiconductor device with increased functional characteristics and a method of manufacturing the same by controlling an oxygen vacancy concentration of a partial area of a channel layer.

According to an embodiment of the present inventive concept, a method of manufacturing a semiconductor device includes forming a bit line on a substrate. A first mold layer is formed on the bit line and includes mold openings defined therein. A channel layer is formed in the mold openings. The channel layer covers the bit line and the first mold layer. A partial area of the channel layer is processed with a neutral beam to change an oxygen vacancy concentration of the partial area of the channel layer. A second mold layer is formed covering the channel layer. The second mold layer and a portion of the channel layer covering an upper surface of the first mold layer are removed. A gate insulating layer covering a sidewall of the channel layer and a word line covering a sidewall of the gate insulating layer are formed. A plurality of insulating patterns is formed filling the mold openings. A contact layer is formed and is connected to the channel layer.

According to an embodiment of the present inventive concept, a method of manufacturing a semiconductor device includes forming a bit line on a substrate. A first mold layer is formed on the bit line. The first mold layer includes a plurality of mold openings defined therein. A channel layer is formed in the plurality of mold openings. The channel layer covers the bit line and the first mold layer. A second mold layer is formed covering the channel layer. A partial area of the channel layer is processed by using a neutral beam passing through the second mold layer. The neutral beam includes neutral oxygen particles. The second mold layer and a portion of the channel layer covering an upper surface of the first mold layer are removed. A gate insulating layer is formed covering a sidewall of the channel layer and a word line is formed covering a sidewall of the gate insulating layer. A plurality of insulating patterns is formed filling the plurality of mold openings. A contact layer is formed that is connected to the channel layer. The processing of the channel layer with the neutral beam includes processing a first portion of the channel layer located on a sidewall of the mold opening with the neutral beam.

According to an embodiment of the present inventive concept, a semiconductor device includes a substrate. A bit line extends in a first horizontal direction on the substrate. A first mold layer is on the bit line. The first mold layer includes a mold opening defined therein. The mold opening exposes a portion of an upper surface of the bit line and extends in a second horizontal direction intersecting with the first horizontal direction. A channel layer is in the mold opening. The channel layer includes a first portion located on a sidewall of the mold opening and a second portion connected to the first portion and extending in the first horizontal direction on the bit line. A word line is located on the first portion and extends in the second direction. A gate insulating layer is located between the word line and the channel layer. A capacitor structure is on the first mold layer. A contact layer is located between the channel layer and the capacitor structure. A first oxygen vacancy concentration of the first portion is different from a second oxygen vacancy concentration of the second portion.

### BRIEF DESCRIPTION OF THE DRAWINGS

Non-limiting embodiments of the present inventive concept will be more clearly understood from the following detailed description taken in conjunction with the accompanying drawings in which:

FIG. 1 is a layout diagram illustrating a semiconductor device according to an embodiment of the present inventive concept;

FIG. 2 is an enlarged layout diagram of a portion of a cell array area of FIG. 1 according to an embodiment of the present inventive concept;

FIG. 3 is a cross-sectional view taken along a line A1-A1′ of FIG. 2 according to an embodiment of the present inventive concept;

FIGS. 4 to 14 are cross-sectional views showing a method of manufacturing a semiconductor device, according to embodiments of the present inventive concept; and

FIGS. 15 and 16 are cross-sectional views showing a method of manufacturing a semiconductor device, according to embodiments of the present inventive concept.

### DETAILED DESCRIPTION OF EMBODIMENTS

Hereinafter, non-limiting embodiments of the present inventive concept will be described in detail with reference to the attached drawings. The same reference numerals are used for the same components in the drawings, and repeated descriptions thereof may be omitted.

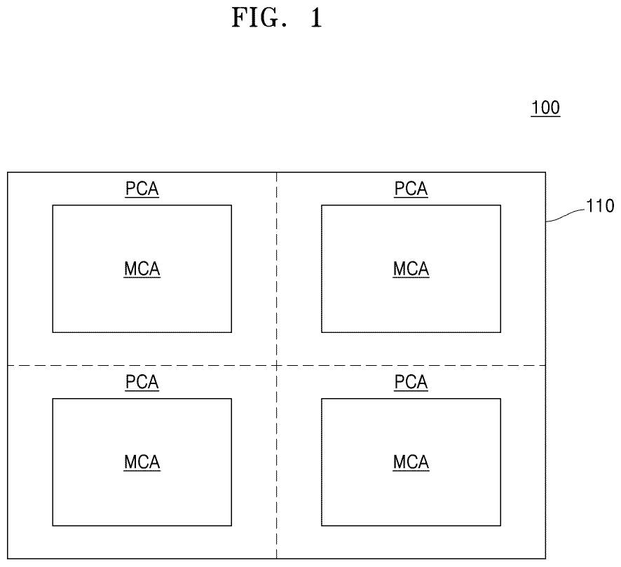

FIG. 1 is a layout diagram illustrating a semiconductor device 100 according to an embodiment.

Referring to FIG. 1, in an embodiment, the semiconductor device 100 may include a substrate 110 including a cell array area MCA and a peripheral circuit area PCA surrounding the cell array area MCA. In some embodiments, the cell array area MCA may be a memory cell area of a dynamic random access memory (DRAM) device, and the peripheral circuit area PCA may be a core area or a peripheral circuit area of the DRAM device. For example, in an embodiment the peripheral circuit area PCA may include a peripheral circuit transistor for transmitting a signal and/or power to a memory cell array included in the cell array area MCA. In an embodiment, a peripheral circuit transistor may constitute various circuits such as a command decoder, a control logic, an address buffer, a row decoder, a column decoder, a sense amplifier, and a data input and output circuit.

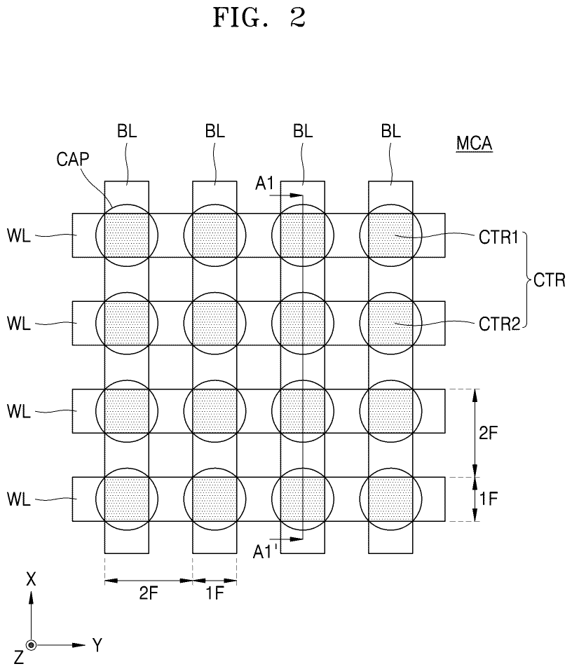

FIG. 2 is an enlarged layout diagram of a portion of the cell array area MCA of FIG. 1.

Referring to FIG. 2, a plurality of bit lines BL extending in a first horizontal direction (e.g., the X direction) and a plurality of word lines WL extending in a second horizontal direction (e.g., the Y direction) may be located on the cell array area MCA of the substrate 110. A plurality of cell transistors CTR may be located at intersections of the plurality of word lines WL and the plurality of bit lines BL. A plurality of cell capacitors CAP may be located on the plurality of cell transistors CTR, respectively.

In an embodiment, the plurality of word lines WL may be spaced apart from each other in the first horizontal direction (e.g., the X direction). In an embodiment, the plurality of cell transistors CTR may include a first cell transistor CTR1 and a second cell transistor CTR2 that are arranged alternately in the first horizontal direction (e.g., the X direction). The first cell transistor CTR1 and the second cell transistor CTR2 may be located on each of the plurality of word lines WL.

In an embodiment, the first cell transistor CTR1 and the second cell transistor CTR2 may have a mirror symmetrical structure with respect to each other. For example, the first cell transistor CTR1 and the second cell transistor CTR2 may have a mirror symmetrical structure with respect to a center line between the first cell transistor CTR1 and the second cell transistor CTR2 that extends in the second horizontal direction (e.g., the Y direction).

In an embodiment, a width (e.g., length in the X direction) of each of the plurality of word lines WL may be 1F, a pitch (e.g., the sum of a width and an interval) of the plurality of word lines WL may be 2F, a width of each of the plurality of bit lines BL may be 1F, a pitch (e.g., the sum of a width and an interval) of each of the plurality of bit lines BL may be 2F, and a unit area for forming one cell transistor CTR may be 4F². Accordingly, the cell transistor CTR may have a crosspoint type that requires a relatively small unit area, which may be increase the integration level of the semiconductor device 100.

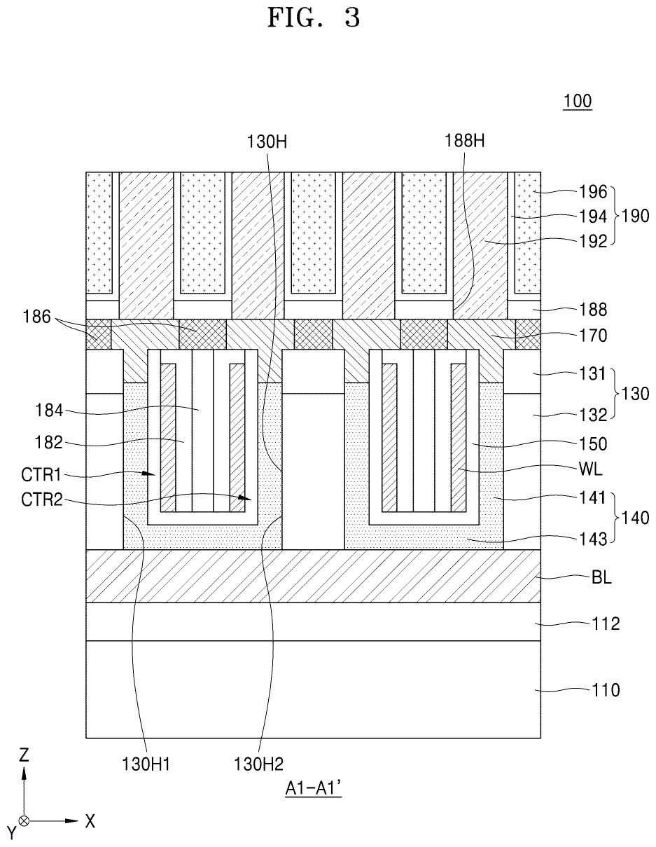

FIG. 3 is a cross-sectional view taken along a line A1-A1′ of FIG. 2.

As shown in FIG. 3, a lower insulating layer 112 may be disposed on the substrate 110. In an embodiment, the substrate 110 may include silicon, for example, single crystalline silicon, polycrystalline silicon, or amorphous silicon. However, embodiments of the present inventive concept are not necessarily limited thereto. In some embodiments, the substrate 110 may include at least one selected from Ge, SiGe, SiC, GaAs, InAs, and InP. In some embodiments, the substrate 110 may include a conductive region, for example, a well doped with an impurity, or a structure doped with an impurity. The lower insulating layer 112 may include an oxide film, a nitride film, or a combination thereof.

A bit line BL extending in the first horizontal direction (e.g., the X direction) may be disposed on the lower insulating layer 112. In an embodiment, the bit line BL may include Ti, TiN, Ta, TaN, W, WN, TiSiN, WSiN, polysilicon, or a combination thereof. For example, in an embodiment, the bit line BL may include a conductive layer and conductive barrier layers disposed on an upper surface and a lower surface of the conductive layer. A bit line insulating layer extending in the first horizontal direction (e.g., the X direction) may be disposed on a sidewall of the bit line BL. For example, the bit line insulating layer may fill a space between two adjacent bit lines BL and may be formed at the same height as the bit lines BL.

A first mold layer 130 may be disposed on (e.g., disposed directly thereon in the Z direction) the bit line BL and the bit line insulating layer. The first mold layer 130 may include a plurality of mold openings 130H defined therein. In an embodiment, the plurality of mold openings 130H may include a first sidewall 130H1 and a second sidewall 130H2 that are opposite to each other (e.g., in the X direction). An upper surface of the bit line BL may be exposed at a bottom portion of each of the plurality of mold openings 130H.

In an embodiment, the first mold layer 130 may include at least one of silicon oxide, silicon nitride, and silicon oxynitride. According to an embodiment, the first mold layer 130 may be formed having a multi-layer structure. For example, the first mold layer 130 may include a first insulating film 131 and a second insulating film 132. In this embodiment, the first insulating film 131 may include silicon nitride and the second insulating film 132 may include silicon oxide. In an embodiment, a vertical direction (e.g., the Z direction) thickness of the second insulating film 132 may be greater than a vertical direction thickness of the first insulating film 131. However, embodiments of the present inventive concept are not necessarily limited thereto.

The second insulating film 132 may be disposed on the bit line BL (e.g., disposed directly thereon in the Z direction). The first insulating film 131 may be disposed on the second insulating film 132 (e.g., disposed directly thereon in the Z direction). In FIG. 3, the first mold layer 130 is shown as including two insulating films. However, embodiments of the present inventive concept are not necessarily limited thereto. For example, the first mold layer 130 may be formed having a single layer structure or may include multiple layers with three or more layers.

In an embodiment, a plurality of channel layers 140 may be disposed on inner walls of the plurality of mold openings 130H. The plurality of channel layers 140 may cover the bit line BL and the first mold layer 130. Each of the plurality of channel layers 140 may include a first portion 141 disposed on the first sidewall 130H1 and the second sidewall 130H2 of the plurality of mold openings 130H and a second portion 143 connected to the first portion 141 and extending from a bottom portion of the plurality of mold openings 130H in the first horizontal direction (e.g., the X direction). One second portion 143 and a pair of first portions 141 connected to both ends of the second portion 143 may be located within one mold opening 130H. In an embodiment, the first portion 141 and the second portion 143 may be formed integrally. For example, each of the plurality of channel layers 140 may have a U-shaped vertical cross section (e.g., in a plane defined in the X and Z directions).

In an embodiment, a first oxygen vacancy concentration of the first portion 141 may be different from a second oxygen vacancy concentration of the second portion 143. For example, the first oxygen vacancy concentration may be lower than the second oxygen vacancy concentration. In an embodiment, the first oxygen vacancy concentration of the first portion 141 may be reduced via passivation by a neutral beam. In contrast, the second oxygen vacancy concentration of the second portion 143 may be maintained constant because the neutral beam is not emitted thereon. A process in which the first portion 141 and the second portion 143 are formed with different oxygen vacancy concentrations by a neutral beam is described in detail below.

In an embodiment, the first oxygen vacancy concentration of the first portion 141 of the channel layer 140 may be reduced by the neutral beam, thereby reducing the conductivity of the first portion 141. The conductivity of the first portion 141 may be reduced, thereby increasing the operating characteristics of a transistor.

In an embodiment, the oxygen vacancy concentration alone of the first portion 141 may be selectively reduced, and the oxygen vacancy concentration of the second portion 143 may be maintained. With respect to the second portion 143, an oxygen vacancy concentration is not passivated by a neutral beam, and thus the second oxygen vacancy concentration may be maintained constant and conductivity may also be maintained constant. In an embodiment of the present inventive concept, the second oxygen vacancy concentration of the second portion 143 in direct contact with the bit line BL is maintained constant and conductivity is also maintained constant, thereby preventing degradation of the characteristics of the transistor (e.g., deterioration of on current).

Composition ratios of the first portion 141 and the second portion 143 may not be affected by processing the channel layer 140 with a neutral beam rather than plasma. For example, composition ratio distribution of the first portion 141 and composition ratio distribution of the second portion 143 may be kept the same (e.g., equalized). However, embodiments of the present inventive concept are not necessarily limited thereto, and the composition ratio distribution of the first portion 141 and the composition ratio distribution of the second portion 143 may be designed differently as needed.

According to an embodiment, there is an effect of shortening a process time by passivating a channel layer by using a neutral beam.

In an embodiment, the first portion 141 of the plurality of channel layers 140 may include a first sidewall and a second sidewall that are opposite to each other (e.g., in the X direction). The first sidewall may be in direct contact with a gate insulating layer 150, and the second sidewall may be in direct contact with the first mold layer 130. Each of the plurality of channel layers 140 may have an upper surface positioned at a lower level than an upper surface of the first mold layer 130.

In an embodiment, the plurality of channel layers 140 may include an oxide semiconductor material. For example, in an embodiment, the plurality of channel layers 140 may include InO, ZnO GaO, IGO, ITO, IGZO, ITGO, IAZO, or a combination thereof. In an embodiment, the plurality of channel layers 140 may include an oxide semiconductor material including indium. For example, the oxide semiconductor material may include at least one of InGaZnOx (IGZO), Sn-doped IGZO, W-doped IGZO, and InZnOx (IZO).

In FIG. 3, each of the plurality of channel layers 140 is shown as including a single layer. However, embodiments of the present inventive concept are not necessarily limited thereto. For example, in an embodiment the plurality of channel layers 140 may be formed having a stacked structure each including a first oxide semiconductor layer and a second oxide semiconductor layer. In this embodiment, the first oxide semiconductor layer and the second oxide semiconductor layer may each include an oxide semiconductor material containing indium.

The gate insulating layer 150 and the word line WL may be sequentially located on the sidewalls of the plurality of channel layers 140. The gate insulating layer 150 may be conformally disposed on the upper surface and the sidewall of each of the plurality of channel layers 140.

The word line WL may be located on the sidewall of the gate insulating layer 150. For example, the gate insulating layer 150 may be located between (e.g., directly therebetween) the word line WL and the channel layer 140. The word line WL may extend in the second horizontal direction (e.g., the Y direction) within the mold opening 130H. In an embodiment, the word line WL may include Ti, TiN, Ta, TaN, W, WN, TiSiN, WSiN, polysilicon, or a combination thereof.

In an embodiment, the channel layer 140 having a U-shaped vertical cross section may be located within one mold opening 130H. A pair of word lines WL may be spaced apart from each other in the first horizontal direction (e.g., the X direction) on the channel layer 140 within one mold opening 130H.

In an embodiment, the gate insulating layer 150 may include at least one material selected from a high-k dielectric material having a higher dielectric constant than silicon oxide and a ferroelectric material. In some embodiments, the gate insulating layer 150 may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), or lead scandium tantalum oxide (PbScTaO).

An insulating liner 182 and a first insulating layer 184 may be located between a pair of word lines WL within each of the plurality of mold openings 130H. A plurality of insulating liners 182 may be disposed on each word line WL. The first insulating layer 184 may be located between the plurality of insulating liners 182 and may have a pillar-shaped cross section. However, the shapes of the insulating liner 182 and the first insulating layer 184 are not necessarily limited thereto and may be designed in various ways.

A contact layer 170 may be formed on the channel layer 140. For example, in an embodiment the contact layer 170 may be in direct contact with an upper surface of the channel layer 140, such as an upper surface of the first portion 141 of the channel layer 140. In some embodiments, a lowermost end of the contact layer 170 may be at a vertical level lower than the upper surface of the word line WL.

The contact layer 170 may connect the channel layer 140 to a capacitor structure 190. In an embodiment, the contact layer 170 may include at least one of a conductive material, for example, a metal, a conductive metal nitride, a conductive metal carbonitride, a conductive metal carbide, a metal silicide, a doped semiconductor material, a conductive metal oxynitride, and a conductive metal oxide, and a two-dimensional (2D) material. However, embodiments of the present inventive concept are not necessarily limited thereto.

In an embodiment, a second insulating layer 186 may be located on both sidewalls of the contact layer 170. Although an upper surface the second insulating layer 186 and the upper surface of the plurality of contact layers 170 are shown to be located at the same level as each other, embodiments of the present inventive concept are not necessarily limited thereto. For example, in some embodiments the upper surface of the second insulating layer 186 may be located at a higher level than the upper surface of the plurality of contact layers 170.

In an embodiment, the insulating liner 182 may include silicon nitride, and the first insulating layer 184 may include silicon oxide. The second insulating layer 186 may include silicon nitride.

In an embodiment, an etch stop layer 188 may be disposed on the contact layer 170 and the second insulating layer 186 (e.g., disposed directly thereon in the Z direction). The etch stop layer 188 may include an opening 188H, and an upper surface of the contact layer 170 may be exposed at a bottom portion of the opening 188H.

The capacitor structure 190 may be disposed on the etch stop layer 188 (e.g., disposed directly thereon in the Z direction). In an embodiment, the capacitor structure 190 may include a lower electrode 192, a capacitor dielectric layer 194, and an upper electrode 196. A sidewall of a bottom portion of the lower electrode 192 may be located within the opening 188H of the etch stop layer 188, and the lower electrode 192 may extend in a vertical direction (e.g., the Z direction). The capacitor dielectric layer 194 may be located on a sidewall of the lower electrode 192, and the upper electrode 196 on the capacitor dielectric layer 194 may cover the lower electrode 192.

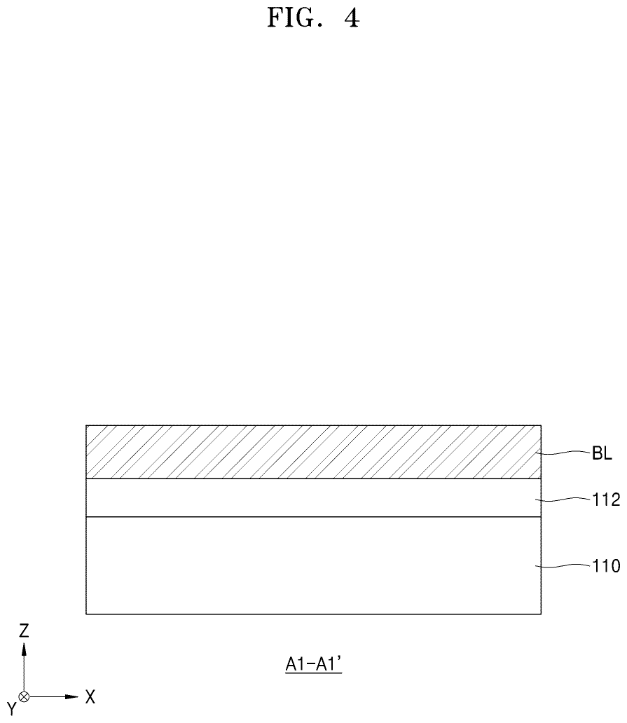

FIGS. 4 to 14 are cross-sectional views showing a method of manufacturing the semiconductor device 100, according to embodiments of the present inventive concept. In FIGS. 4 to 14, the same reference numerals as in FIGS. 1 to 3 indicate the same components.

Referring to FIG. 4, the lower insulating layer 112 is formed on the substrate 110 (e.g. formed directly thereon in the Z direction). The plurality of bit lines BL extending in the first horizontal direction (e.g., the X direction) and a bit line insulating layer filling a space between the plurality of bit lines BL may then be formed on the lower insulating layer 112 (e.g., formed directly thereon in the Z direction). In an embodiment, each of the plurality of bit lines BL may include a conductive barrier layer, a conductive layer, and a conductive barrier layer that are arranged sequentially.

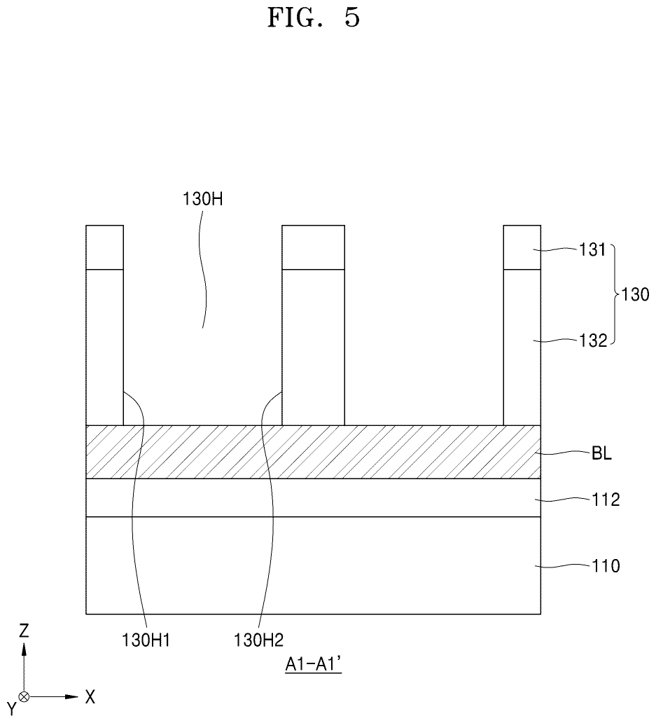

Referring to FIG. 5, the first mold layer 130 may be formed on the plurality of bit lines BL and the bit line insulating layer (e.g., formed directly thereon in the Z direction). In some embodiments, the first mold layer 130 may be formed having a stacked structure. In an embodiment, the first mold layer 130 may include at least one of silicon oxide, silicon nitride, and silicon oxynitride and may be formed to have a relatively large height in the vertical direction (e.g., the Z direction).

In an embodiment, the first mold layer 130 may include at least one of silicon oxide, silicon nitride, and silicon oxynitride. According to an embodiment, the first mold layer 130 may be formed having a multi-layer structure. For example, in an embodiment the first mold layer 130 may include the first insulating film 131 and the second insulating film 132 disposed directly below the first insulating film 131. In this embodiment, the first insulating film 131 may include silicon nitride and the second insulating film 132 may include silicon oxide. In an embodiment, a vertical direction (e.g., the Z direction) thickness of the second insulating film 132 may be greater than a vertical direction thickness of the first insulating film 131. However, embodiments of the present inventive concept are not necessarily limited thereto.

In an embodiment, the second insulating film 132 may be disposed on the bit line BL (e.g., disposed directly thereon in the Z direction). The first insulating film 131 may be disposed on the second insulating film 132 (e.g., disposed directly thereon in the Z direction). In FIG. 5, the first mold layer 130 is shown as including two insulating films. However, embodiments of the present inventive concept are not necessarily limited thereto. For example, in some embodiments the first mold layer 130 may be formed having a single layer structure or may include multiple layers with three or more layers.

The plurality of first mold layers 130 may extend in the second horizontal direction (e.g., the Y direction) and may be formed at equal intervals in the first horizontal direction (e.g., the X direction). The mold opening 130H extending lengthwise in the second horizontal direction (e.g., Y direction) may be formed between the plurality of first mold layers 130.

In an embodiment, the mold opening 130H may be formed by forming a mask pattern on the first mold layer 130 and using the mask pattern as an etch mask. The upper surface of the bit line BL may be exposed at a bottom portion of each of the plurality of mold openings 130H. The plurality of mold openings 130H may include the first sidewall 130H1 and the second sidewall 130H2 that are opposite to each other (e.g., in the X direction).

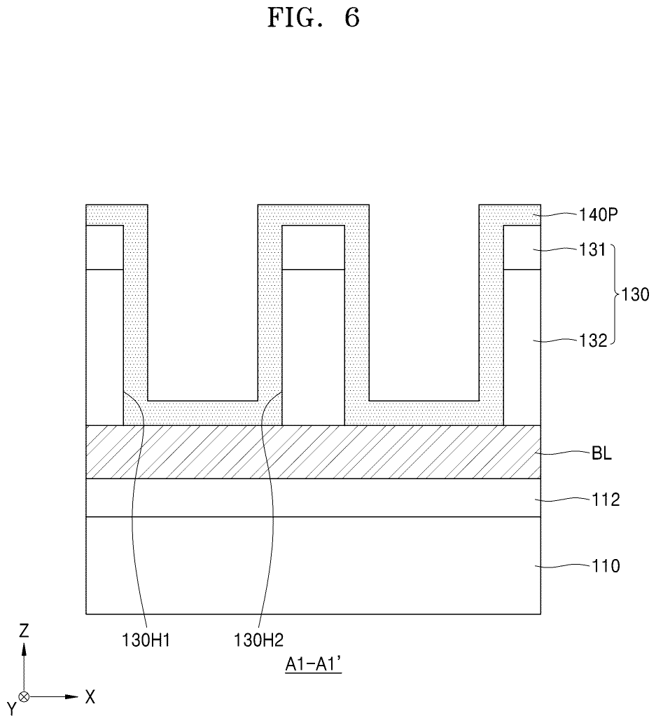

Referring to FIG. 6, a preliminary channel layer 140P may be formed on (e.g., formed directly thereon) the first mold layer 130 to conformally cover an inner wall of the mold opening 130H.

In an embodiment, the preliminary channel layer 140P may be formed using an oxide semiconductor material. The preliminary channel layer 140P may include an oxide semiconductor material containing indium. For example, in an embodiment the oxide semiconductor material may include at least one of IGZO, Sn-doped IGZO, W-doped IGZO, and IZO.

In an embodiment, the preliminary channel layer 140P may be formed using at least one of a chemical vapor deposition (CVD) process, a low pressure CVD process, a plasma enhanced CVD process, a metal organic CVD (MOCVD) process, and an atomic layer deposition process. However, embodiments of the present inventive concept are not necessarily limited thereto.

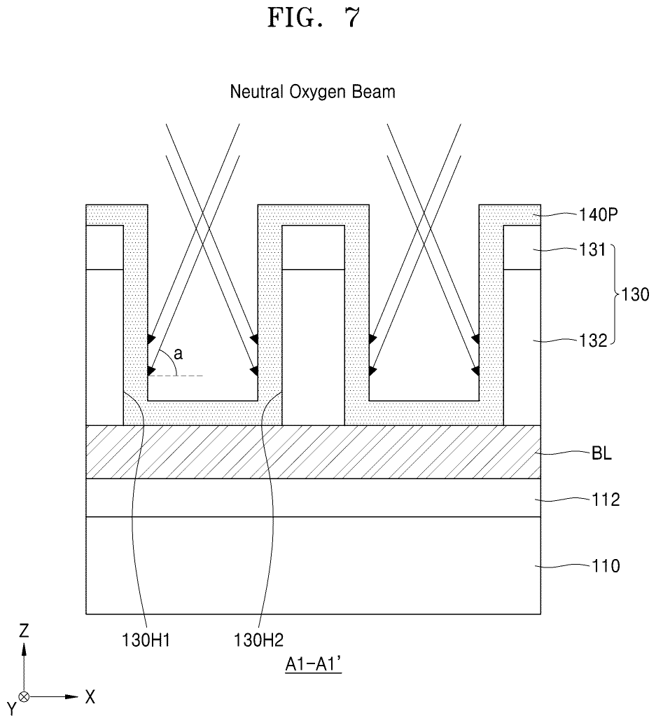

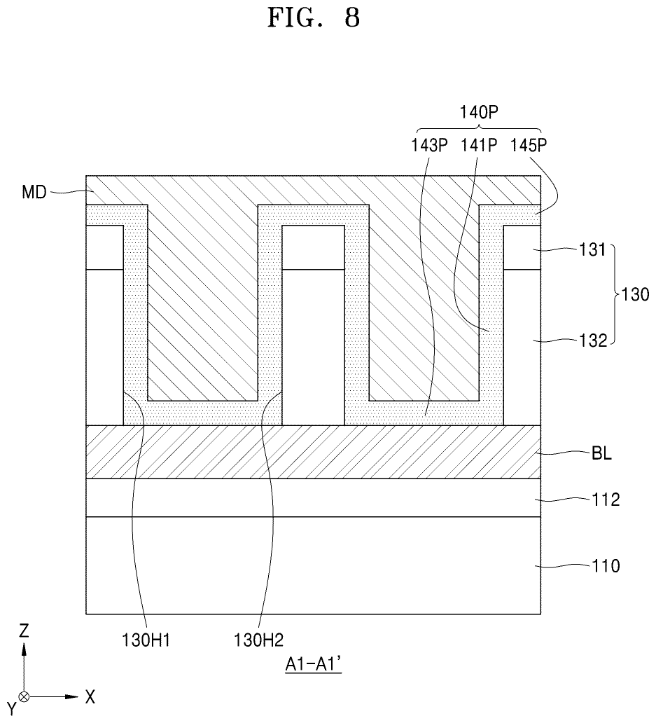

Referring to FIG. 7, the manufacturing method may include an operation of processing a partial area of the preliminary channel layer 140P with a neutral beam. The neutral beam may include neutral oxygen particles. In this embodiment, the neutral beam may be emitted only to a partial area of the preliminary channel layer 140P. For example, in an embodiment the neutral beam may be emitted to a first portion 141P (refer to FIG. 8) of the preliminary channel layer 140P disposed on the sidewalls 130H1 and 130H2 of the mold opening 130H. The neutral beam may be emitted to a third portion 145P (refer to FIG. 8) of the preliminary channel layer 140P, which covers the upper surface of the first mold layer 130. In an embodiment, the neutral beam may not be emitted to a second portion 143P (refer to FIG. 8) of the preliminary channel layer 140P, which is connected to the first portion 141P of the preliminary channel layer 140P and extends in a first horizontal direction (e.g., the X direction).

In an embodiment, an angle of incidence “a” of the neutral beam with respect to the sidewalls 130H1 and 130H2 of the mold opening 130H may be adjusted. For example, the angle of incidence “a” of the neutral beam with respect to the first portion 141P of the preliminary channel layer 140P may be adjusted. For example, the angle of incidence “a” of the neutral beam may be adjusted by controlling a neutral beam device. The angle of incidence “a” of the neutral beam may be adjusted to an angle at which the neutral beam is not emitted to the second portion 143P of the preliminary channel layer 140P. For example, in an embodiment the angle of incidence “a” of the neutral beam may be adjusted to less than about 90°. The angle of incidence “a” of the neutral beam may be adjusted considering a size of the mold opening 130H. For example, the angle of incidence “a” of the neutral beam may be adjusted depending on a width and/or a height of the mold opening 130H. The angle of incidence “a” of the neutral beam may be adjusted according to the width and/or height of the mold opening 130H to prevent the neutral beam from being emitted to (e.g., reach) the second portion 143P of the preliminary channel layer 140P.

In an embodiment, to adjust the angle of incidence “a” of the neutral beam, the substrate 110 may be rotated at a certain angle. To adjust the angle of incidence “a” of the neutral beam, the substrate 110 may be tilted at a certain angle. In an embodiment, to adjust the angle of incidence “a” of the neutral beam, the manufacturing method may include an operation of at least one of rotating the substrate 110 at a certain angle and tilting the substrate 110 at a certain angle.

The operation of processing the preliminary channel layer 140P with a neutral beam may include an operation of controlling the neutral beam device to change a process condition. For example, in an embodiment at least one of process temperature, process time, process pressure, RF power, and neutral beam energy may be adjusted. In an embodiment, the process temperature may be less than or equal to about 100° C., the process time may be within about 10 minutes, and the process pressure may be within about 1 Torr. The RF power may be within about 2,000 W, and the neutral beam energy may be within about 100 eV.

Referring to FIG. 8, an oxygen vacancy concentration in a partial area of the preliminary channel layer 140P may be changed by emitting a neutral beam to the preliminary channel layer 140P. For example, oxygen vacancy concentrations of the first portion 141P and the third portion 145P of the preliminary channel layer 140P, to which a neutral beam is emitted, may be changed. In an embodiment the oxygen vacancy concentrations of the first portion 141P and the third portion 145P may be lowered. For example, the oxygen vacancy concentration of the first portion 141P and the third portion 145P may be changed to be lower than the oxygen vacancy concentration of the second portion 143P. In this embodiment, the composition ratio distribution of the first portion and the composition ratio distribution of the second portion may be processed to be the same as each other (e.g., equalized).

In an embodiment, a second mold layer MD may be formed to cover the preliminary channel layer 140P and fill a portion of the mold opening 130H. The plurality of second mold layers MD may extend lengthwise in the second horizontal direction (e.g., the Y direction).

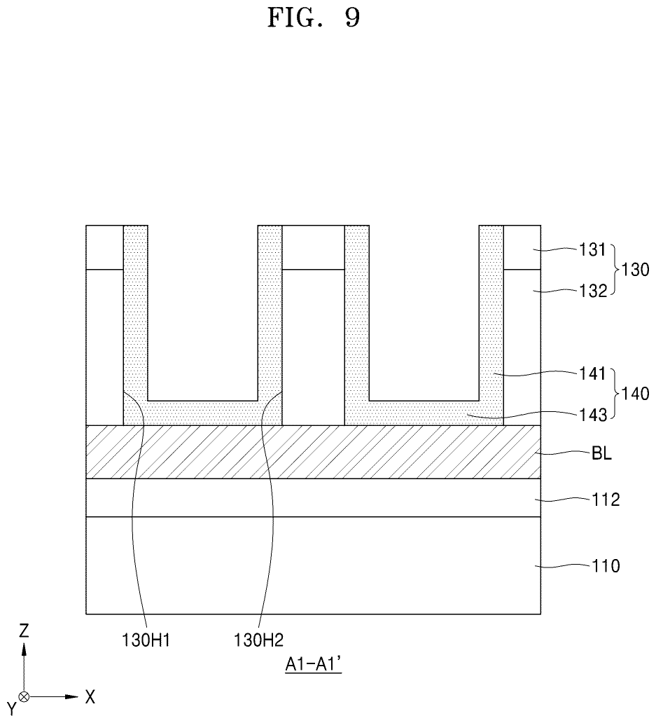

Referring to FIG. 9, in an embodiment the plurality of channel layers 140 may be formed by etching back the second mold layer MD. When removing the second mold layer MD, a portion of the preliminary channel layer 140P may also be removed. For example, in an embodiment, the third portion 145P (refer to FIG. 8) of the preliminary channel layer 140P, which covers the upper surface of the first mold layer 130, may be removed to form the plurality of channel layers 140 which solely includes the first portion 141 and the second portion 143.

In an embodiment, the preliminary channel layer 140P may be removed to leave the channel layer 140 within the mold opening 130H. In an embodiment, the preliminary channel layer 140P may be removed by an etch-back process or a planarization process.

The channel layer 140 having a U-shaped vertical cross section may be formed within the mold opening 130H by the etch-back process or the planarization process. As a portion of the preliminary channel layer 140P that is disposed on the upper surface of the first mold layer 130 is removed, the upper surface of the first mold layer 130 may be exposed. In an embodiment, the upper surface of the channel layer 140 may be at the same level as the upper surface of the first mold layer 130.

Each of the plurality of channel layers 140 may cover the inner wall and the lower surface of the mold opening 130H. Each of the plurality of channel layers 140 may be formed to have a U-shaped vertical cross section. In an embodiment, a vertical direction (e.g., the Z direction) level of the upper surface of the channel layer 140 may be the same as a vertical direction (e.g., the Z direction) level of the upper surface of the first mold layer 130.

In an embodiment of the present inventive concept, the method of manufacturing the semiconductor device 100 may reduce the first oxygen vacancy concentration of the first portion 141 of the channel layer 140 by a neutral beam, thereby reducing the conductivity of the first portion 141. The operating characteristics of the transistor may be increased by reducing the conductivity of the first portion 141.

In an embodiment, the oxygen vacancy concentration of the first portion 141 may be selectively reduced, and the oxygen vacancy concentration of the second portion 143 may be maintained. In the case of the second portion 143, an oxygen vacancy concentration is not passivated by a neutral beam, and thus the second oxygen vacancy concentration may be maintained constant and conductivity may also be maintained constant. In an embodiment of the present inventive concept, the second oxygen vacancy concentration of the second portion 143 in direct contact with the bit line BL is maintained constant and the conductivity is also maintained constant, thereby preventing deterioration of the characteristics of the transistor (e.g., deterioration of on current).

Composition ratios of the first portion 141 and the second portion 143 may not be affected by processing the channel layer 140 with a neutral beam rather than plasma. For example, the composition ratio distribution of the first portion 141 and the composition ratio distribution of the second portion 143 may be kept the same (e.g., may be maintained).

The process of processing the channel layer 140 by using a neutral beam may be performed at room temperature and may have an effect of shortening the process time compared to an existing channel layer processing process. For example, in an embodiment a process of processing the channel layer 140 by using a neutral beam may be performed within about 10 minutes.

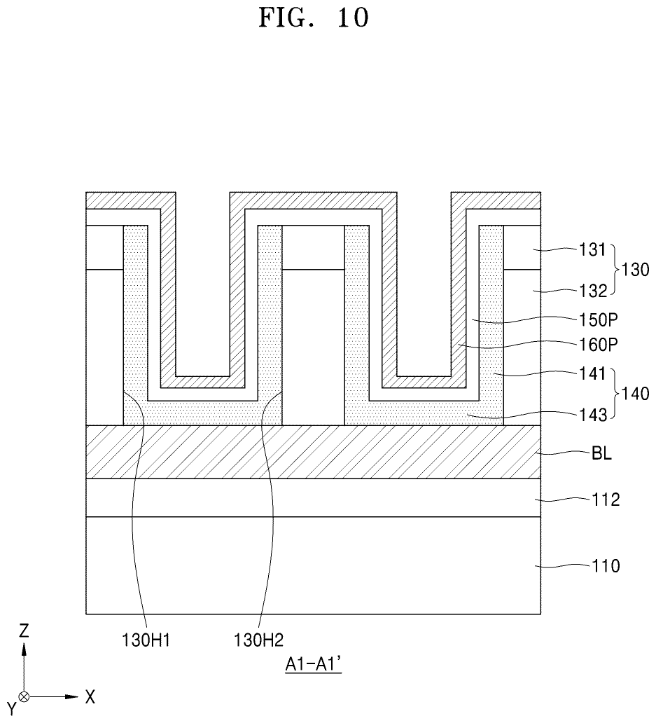

Referring to FIG. 10, a preliminary gate insulating layer 150P and a preliminary gate electrode layer 160P that cover the channel layer 140 and the first mold layer 130 may be sequentially formed. The preliminary gate insulating layer 150P may conformally cover the sidewall and the upper surface of the channel layer 140. The preliminary gate insulating layer 150P may cover the upper surface of the first mold layer 130. The preliminary gate electrode layer 160P may conformally cover a lateral surface and an upper surface of the preliminary gate insulating layer 150P. In an embodiment, each of the preliminary gate insulating layer 150P and the preliminary gate electrode layer 160P may be formed to have a U-shaped vertical cross section (e.g., in a plane defined in the X and Z directions).

In an embodiment, each of the plurality of channel layers 140 may include the first portion 141 disposed on (e.g., disposed directly thereon) the first sidewall 130H1 and the second sidewall 130H2 of the plurality of mold openings 130H and the second portion 143 connected to the first portion 141 and extending from (e.g., extending directly from) the bottom portion of the plurality of mold openings 130H in the first horizontal direction (e.g., the X direction). The first portion 141 may include the first sidewall and the second sidewall that are opposite to each other. The first sidewall of the first portion 141 may be exposed, and the second sidewall of the first portion 141 may be surrounded by the first mold layer 130.

In an embodiment, the preliminary gate insulating layer 150P may include at least one material selected from a high-k dielectric material having a higher dielectric constant than silicon oxide and a ferroelectric material. In some embodiments, the preliminary gate insulating layer 150P may include at least one material selected from HfO, HfSiO, HfON, HfSiON, LaO, LaAIO, ZrO, ZrSiO, ZrON, ZrSiON, TaO, TiO, BaSrTiO, BaTIO, PZT, STB, BFO, SrTiO, YO, AIO, or PbScTaO.

In an embodiment, the preliminary gate electrode layer 160P may be formed using Ti, TiN, Ta, TaN, W, WN, TiSiN, WSiN, polysilicon, or a combination thereof.

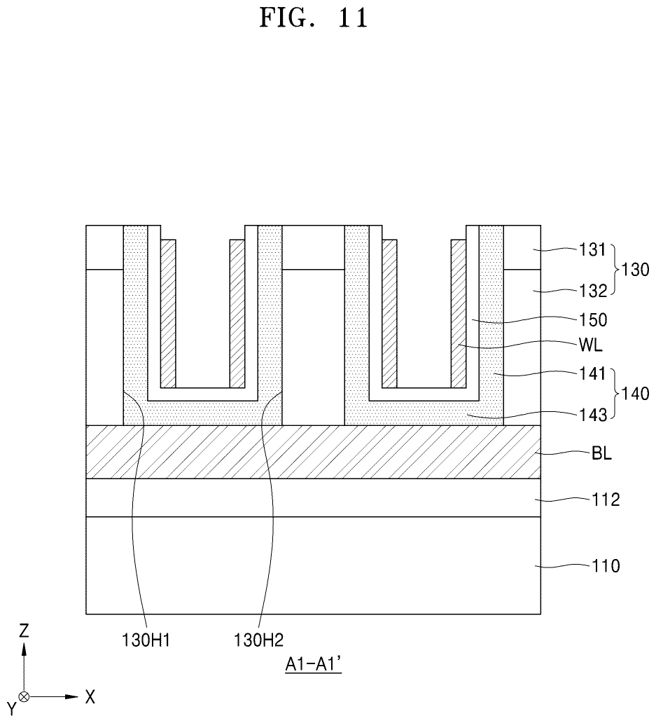

Referring to FIG. 11, in an embodiment, portions of the preliminary gate insulating layer 150P and the preliminary gate electrode layer 160P, which cover at least a portion of the upper surface of the plurality of first mold layers 130 and the upper surface of the plurality of channel layers 140, may be removed to form the gate insulating layer 150 and the word line WL.

In an embodiment, a portion of the preliminary gate electrode layer 160P on the bottom portion of the gate insulating layer 150 may be removed by performing an etching process to expose the upper surface of the gate insulating layer 150. Portions of the preliminary gate insulating layer 150P and the preliminary gate electrode layer 160P may remain on the first sidewall 130H1 and the second sidewall 130H2 of the mold opening 130H. Portions of the preliminary gate insulating layer 150P and the preliminary gate electrode layer 160P, which are disposed on the upper surface of the first mold layer 130, may also be removed by an etching process.

The gate insulating layer 150 may be formed to cover a lateral surface of the channel layer 140 within the mold opening 130H and may extend in the vertical direction (e.g., the Z direction). The plurality of gate insulating layers 150 may each be disposed on the first sidewall 130H1 and the second sidewall 130H2 of the plurality of mold openings 130H. The gate insulating layer 150 may cover a portion of the first portion 141 of the channel layer 140.

In an embodiment, the preliminary gate electrode layer 160P may be separated into two word lines WL that are disposed on the first sidewall 130H1 and the second sidewall 130H2 of the plurality of mold openings 130H, respectively. The plurality of word lines WL may be formed to cover the gate insulating layer 150 and extend in the vertical direction (e.g., the Z direction) within the mold opening 130H. In an embodiment, the word line WL may include Ti, TiN, Ta, TaN, W, WN, TiSiN, WSiN, polysilicon, or a combination thereof. However, embodiments of the present inventive concept are not necessarily limited thereto.

In some embodiments, the plurality of word lines WL may be formed to face each other within one mold opening 130H. In an embodiment, the plurality of word lines WL may be spaced apart from each other in the first horizontal direction (e.g., the X direction) and each may extend lengthwise in the second horizontal direction (e.g., the Y direction).

In an embodiment, a portion of an upper portion of the word line WL in the vertical direction (e.g., the Z direction) may also be removed through an etching process. Accordingly, a vertical level of an uppermost end of the word line WL may be lower than a vertical level of an uppermost end of the channel layer 140.

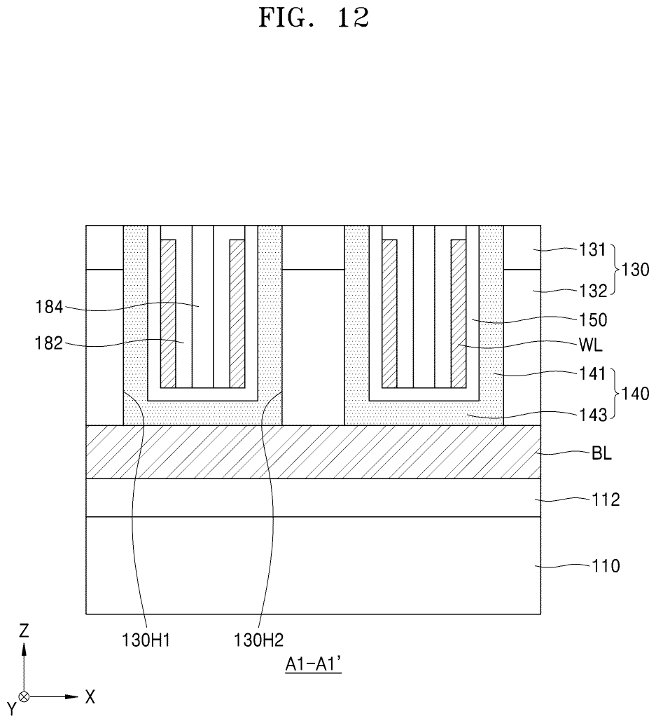

Referring to FIG. 12, an insulating pattern may be formed inside the mold opening 130H. For example, in an embodiment the insulating liner 182 and a first insulating layer 184 may be formed inside the mold opening 130H. The insulating liner 182 and the first insulating layer 184 may be located between two adjacent word lines WL, and the insulating liner 182 may be disposed on the upper surface of the channel layer 140, such as an upper surface of the second portion 143 of the channel layer 140. In an embodiment, the insulating liner 182 and the first insulating layer 184 may be formed through an etch-back process or a planarization process.

Accordingly, the first cell transistor CTR1 and the second cell transistor CTR2 may be formed within the mold opening 130H. The first cell transistor CTR1 and the second cell transistor CTR2 may be spaced apart from each other in the first horizontal direction (e.g., the X direction) and may be arranged to have a mirror symmetrical shape with respect to each other (refer to FIG. 3).

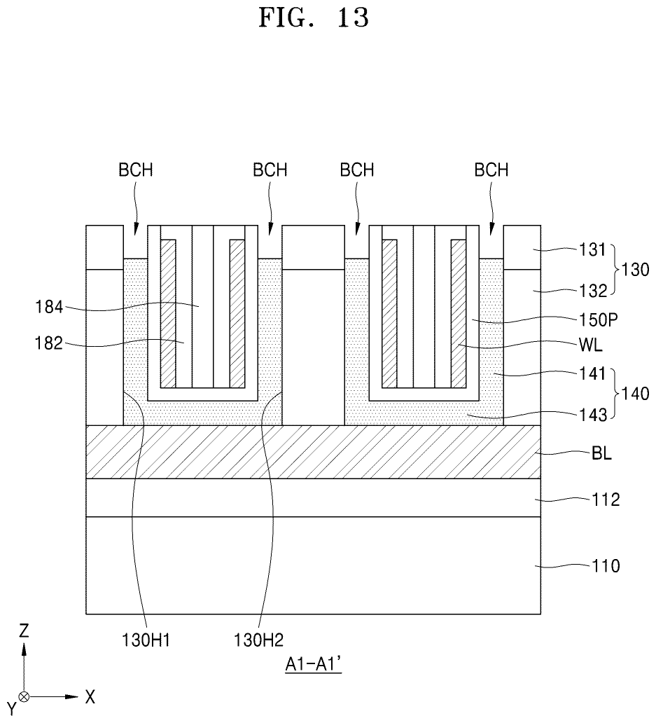

Referring to FIG. 13, in an embodiment a portion of an upper portion of the channel layer 140 may be removed by performing a recess process. A contact hole BCH may be formed by removing the portion of the upper portion of the channel layer 140. The uppermost end of the channel layer 140 may be positioned at a level lower than an uppermost end of the word line WL by removing the portion of the upper portion of the channel layer 140.

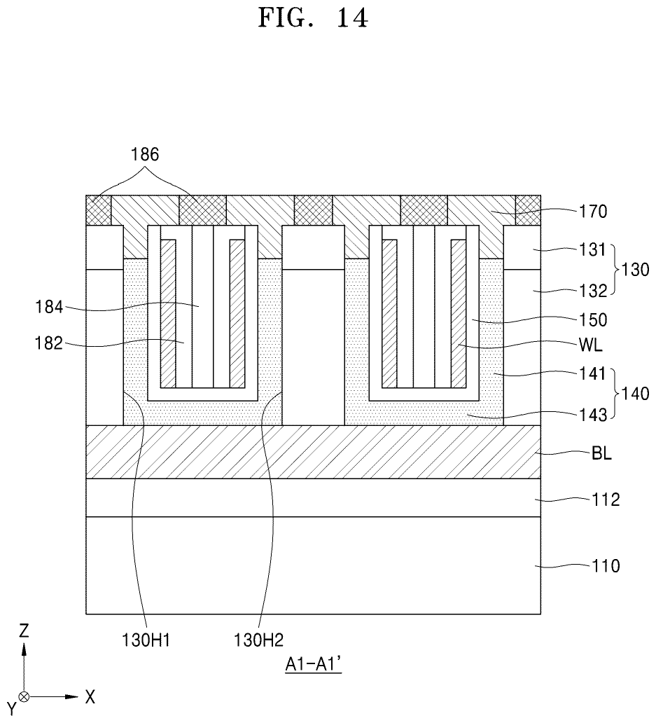

Referring to FIG. 14, the contact layer 170 and the second insulating layer 186 may be formed.

In an embodiment, a mask pattern may be formed on a contact conductive layer, a portion of the contact conductive layer may be removed using the mask pattern to form the contact layer 170, and the second insulating layer 186 may be formed in an area from which the contact conductive layer is removed. In an embodiment, the contact layer 170 may include Ti, TiN, Ta, TaN, W, WN, TiSiN, WSiN, polysilicon, or a combination thereof.

In an embodiment, the second insulating layer 186 may be formed using silicon nitride. A sidewall of the contact layer 170 may be surrounded by the second insulating layer 186, and a bottom surface of the contact layer 170 may be covered by portions of the first mold layer 130, the channel layer 140, the gate insulating layer 150, or the insulating liner 182.

Referring back to FIG. 3, the etch stop layer 188 may be formed on (e.g., formed directly thereon in the third direction DR3) the contact layer 170 and the second insulating layer 186. The etch stop layer 188 may include the opening 188H, and the upper surface of the contact layer 170 may be exposed at the bottom portion of the opening 188H. In an embodiment, the lower electrode 192, the capacitor dielectric layer 194, and the upper electrode 196 may then be sequentially formed on the etch stop layer 188.

The plurality of lower electrodes 192 may be formed to extend in the vertical direction (e.g., the Z direction) from the upper surface of the contact layer 170 exposed at a lower surface of the opening 188H of the etch stop layer 188. In an embodiment, the capacitor dielectric layer 194 and the upper electrode 196 may then be sequentially formed on the plurality of lower electrodes 192 to form the semiconductor device 100 including the plurality of capacitor structures 190.

In this embodiment, the lower electrode 192 is shown as being formed in a pillar shape extending in the vertical direction (e.g., the Z direction) from the upper surface of the contact layer 170. However, embodiments of the present inventive concept are not necessarily limited thereto, and the lower electrode 192 may be formed to have a cylindrical shape extending in the vertical direction (e.g., the Z direction) from the upper surface of the contact layer 170. The capacitor dielectric layer 194 may be formed to extend conformally along a profile of the lateral surface and the upper surface of the plurality of lower electrodes 192, and an upper surface of the etch stop layer 188. The upper electrode 196 may be formed to cover the capacitor dielectric layer 194.

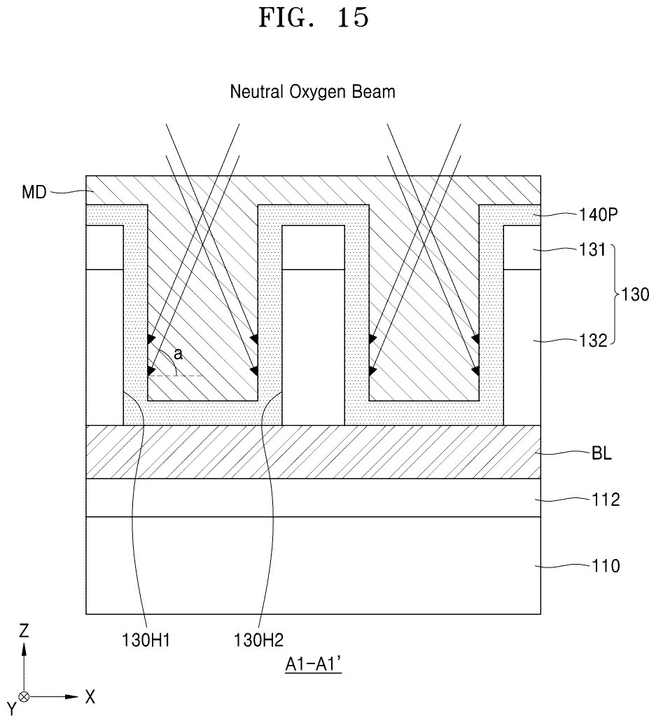

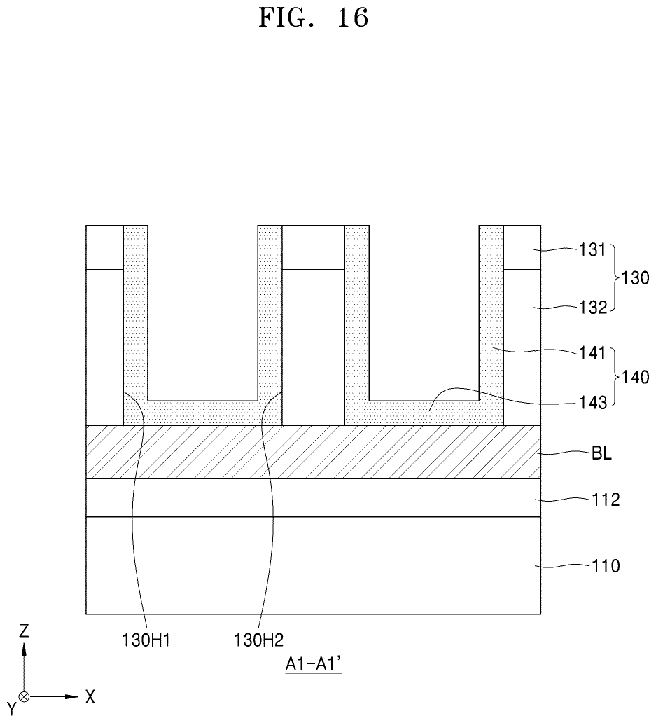

FIGS. 15 and 16 are cross-sectional views showing a method of manufacturing a semiconductor device, according to embodiments of the present inventive concept. In FIGS. 15 to 16, the same reference numerals as in FIGS. 1 to 3 indicate the same components. Descriptions of parts that are common to the manufacturing method of the semiconductor device 100 described with reference to FIGS. 3 to 6 and 9 to 14 will be omitted for economy of description.

After processes of the manufacturing method of the semiconductor device 100 of FIGS. 3 to 6 described above are performed, the process of FIG. 15 may be performed. Referring to FIG. 15, the second mold layer MD may be formed to cover the preliminary channel layer 140P and fill a portion of the mold opening 130H. In an embodiment, the plurality of second mold layers MD may extend lengthwise in the second horizontal direction (e.g., the Y direction).

In an embodiment, a partial area of the preliminary channel layer 140P which is covered by the second mold layer MD may then be processed with a neutral beam. The neutral beam may include neutral oxygen particles. In this embodiment, the neutral beam may pass through the second mold layer MD and be emitted solely to a partial area of the preliminary channel layer 140P. For example, the neutral beam may be emitted to the first portion of the preliminary channel layer 140P disposed on the sidewalls 130H1 and 130H2 of the mold opening 130H. The neutral beam may also be emitted to the third portion of the preliminary channel layer 140P, which covers the upper surface of the first mold layer 130. In this embodiment, the neutral beam may not be emitted to the second portion of the preliminary channel layer 140P, which is connected to the first portion of the preliminary channel layer 140P and extends in the first horizontal direction.

In an embodiment, the angle of incidence “a” of the neutral beam with respect to the sidewalls 130H1 and 130H2 of the mold opening 130H may be adjusted. For example, the angle of incidence “a” of the neutral beam with respect to the first portion of the preliminary channel layer 140P may be adjusted. In an embodiment, the angle of incidence “a” of the neutral beam may be adjusted by controlling the neutral beam device. The angle of incidence “a” of the neutral beam may be adjusted to an angle at which the neutral beam is not emitted to the second portion of the preliminary channel layer 140P. For example, in an embodiment the angle of incidence “a” of the neutral beam may be adjusted to less than about 90°. The angle of incidence “a” of the neutral beam may be adjusted depending on the width and/or height of the mold opening 130H. The angle of incidence “a” of the neutral beam may be adjusted depending on the width and/or height of the mold opening 130H to prevent the neutral beam from being emitted to the second portion of the preliminary channel layer 140P.

In an embodiment, to adjust the angle of incidence “a” of the neutral beam, the substrate 110 may be rotated at a certain angle. To adjust the angle of incidence “a” of the neutral beam, the substrate 110 may be tilted at a certain angle. To adjust the angle of incidence “a” of the neutral beam, the manufacturing method may include at least one of rotating the substrate 110 at a certain angle and tilting the substrate 110 at a certain angle.

The processing of the preliminary channel layer 140P with the neutral beam may include controlling a neutral beam device to change a process condition. For example, in an embodiment, at least one of a process temperature, process time, process pressure, RF power, and neutral beam energy may be adjusted. In an embodiment, the process temperature may be less than or equal to about 100° C., the process time may be within about 10 minutes, and the process pressure may be within about 1 Torr. The RF power may be within about 2,000 W, and the neutral beam energy may be within about 100 eV.

An oxygen vacancy concentration in a partial area of the preliminary channel layer 140P may be changed by emitting a neutral beam to the preliminary channel layer 140P. For example, oxygen vacancy concentrations of the first portion and the third portion of the preliminary channel layer 140P, to which a neutral beam is emitted, may be changed. In this embodiment, the oxygen vacancy concentrations of the first portion and the third portion may be lowered. For example, the oxygen vacancy concentrations of the first portion and the third portion may be changed to be lower than the oxygen vacancy concentration of the second portion. In this embodiment, processing may be performed to equalize the composition ratio distribution of the first portion and the composition ratio distribution of the second portion.

Referring to FIG. 16, in an embodiment the plurality of channel layers 140 may be formed by etching back the second mold layer MD. When the second mold layer MD is removed, a portion of the preliminary channel layer 140P may also be removed. For example, in an embodiment the third portion of the preliminary channel layer 140P, which covers the upper surface of the first mold layer 130, may be removed to form the plurality of channel layers 140.

In an embodiment, the preliminary channel layer 140P may be removed to leave the channel layer 140 within the mold opening 130H. In an embodiment, the preliminary channel layer 140P may be removed by an etch-back process or a planarization process.

The semiconductor device 100 of an embodiment of the present inventive concept may be manufactured by repeatedly performing the processes of the manufacturing method of the semiconductor device 100 described with reference to FIGS. 9 to 14.

As above, non-limiting embodiments have been disclosed in the drawings and specification. In this specification, embodiments have been described using certain terms, but these are simply used for the purpose of explaining the technical spirit of the present inventive concept and is not used to limit the meaning or scope of the present inventive concept. Therefore, those skilled in the art will understand that various modifications and other equivalent embodiments are possible therefrom. Therefore, the true technical scope of embodiments of the present inventive concept are not limited by the described embodiments.

While the present inventive concept has been particularly shown and described with reference to non-limiting embodiments thereof, it will be understood that various changes in form and details may be made therein without departing from the spirit and scope of the present inventive concept.

What is claimed is:

1. A method of manufacturing a semiconductor device, the method comprising:
forming a bit line on a substrate;
forming a first mold layer on the bit line, the first mold layer including a plurality of mold openings defined therein;
forming a channel layer in the plurality of mold openings, the channel layer covering the bit line and the first mold layer;
processing a partial area of the channel layer with a neutral beam to change an oxygen vacancy concentration of the partial area of the channel layer;
forming a second mold layer covering the channel layer;
removing the second mold layer and a portion of the channel layer that covers an upper surface of the first mold layer;
forming a gate insulating layer covering a sidewall of the channel layer and a word line covering a sidewall of the gate insulating layer;
forming a plurality of insulating patterns filling the plurality of mold openings; and
forming a contact layer connected to the channel layer.

2. The method of claim 1, wherein the processing of the partial area of the channel layer with the neutral beam includes processing a first portion of the channel layer located on a sidewall of the plurality of mold openings with the neutral beam.

3. The method of claim 1, wherein the processing of the partial area of the channel layer with the neutral beam includes differentiating a first oxygen vacancy concentration of a first portion of the channel layer located on the sidewall of the plurality of mold openings from a second oxygen vacancy concentration of a second portion of the channel layer connected to the first portion and extending in a first horizontal direction.

4. The method of claim 3, wherein the first oxygen vacancy concentration is lower than the second oxygen vacancy concentration.

5. The method of claim 3, wherein the processing of the partial area of the channel layer with the neutral beam includes performing the processing to equalize composition ratio distribution of the first portion and composition ratio distribution of the second portion.

6. The method of claim 3, wherein the processing of the partial area of the channel layer with the neutral beam includes adjusting an angle of incidence of the neutral beam to prevent the neutral beam from reaching the second portion.

7. The method of claim 6, wherein the adjusting of the angle of incidence of the neutral beam includes adjusting the angle of incidence to less than about 90°.

8. The method of claim 6, wherein the adjusting of the angle of incidence of the neutral beam includes at least one of rotating the substrate and tilting the substrate.

9. The method of claim 6, wherein the adjusting of the angle of incidence of the neutral beam includes adjusting the angle of incidence considering a size of the plurality of mold openings.

10. The method of claim 1, wherein the processing of the partial area of the channel layer with the neutral beam includes adjusting at least one of process temperature, process time, process pressure, RF power, and neutral beam energy.

11. The method of claim 1, wherein the neutral beam includes neutral oxygen particles.

12. A method of manufacturing a semiconductor device, the method comprising:
forming a bit line on a substrate;
forming a first mold layer on the bit line, the first mold layer including a plurality of mold openings defined therein;
forming a channel layer in the plurality of mold openings, the channel layer covering the bit line and the first mold layer;
forming a second mold layer covering the channel layer;
processing a partial area of the channel layer by using a neutral beam passing through the second mold layer, the neutral beam including neutral oxygen particles;
removing the second mold layer and a portion of the channel layer covering an upper surface of the first mold layer;
forming a gate insulating layer covering a sidewall of the channel layer and a word line covering a sidewall of the gate insulating layer;
forming a plurality of insulating patterns filling the plurality of mold openings; and
forming a contact layer connected to the channel layer,
wherein the processing of the channel layer with the neutral beam includes
processing a first portion of the channel layer located on a sidewall of the plurality of mold openings with the neutral beam.

13. The method of claim 12, wherein the processing of the channel layer with the neutral beam includes differentiating a first oxygen vacancy concentration of the first portion from a second oxygen vacancy concentration of a second portion of the channel layer connected to the first portion and extending in a first horizontal direction.

14. The method of claim 13, wherein the first oxygen vacancy concentration is lower than the second oxygen vacancy concentration.

15. The method of claim 13, wherein the processing of the channel layer with the neutral beam includes adjusting an angle of incidence of the neutral beam to prevent the neutral beam from reaching the second portion.

16. The method of claim 12, wherein the processing of the channel layer with the neutral beam includes adjusting at least one of process temperature, process time, process pressure, and neutral beam energy.

17. A method of manufacturing a semiconductor device, the method comprising:
forming a bit line on a substrate;
forming a first mold layer on the bit line, the first mold layer including a plurality of mold openings defined therein;
forming a channel layer in the plurality of mold openings, the channel layer covering the bit line and the first mold layer;
processing a first portion of the channel layer located on a sidewall of the plurality of mold openings with a neutral beam to change an oxygen vacancy concentration of the first portion of the channel layer, the neutral beam including neutral oxygen particles;
forming a second mold layer covering the channel layer;
removing the second mold layer and a portion of the channel layer that covers an upper surface of the first mold layer;
forming a gate insulating layer covering a sidewall of the channel layer and a word line covering a sidewall of the gate insulating layer;
forming a plurality of insulating patterns filling the plurality of mold openings;
forming a contact layer connected to the channel layer and insulating layer covering a sidewall of the contact layer; and
forming a capacitor structure connected to the contact layer.

18. The method of claim 17, wherein the processing of first portion of the channel layer with the neutral beam includes differentiating a first oxygen vacancy concentration of the first portion from a second oxygen vacancy concentration of a second portion of the channel layer connected to the first portion and extending in a first horizontal direction.

19. The method of claim 18, wherein the first oxygen vacancy concentration is lower than the second oxygen vacancy concentration.

20. The method of claim 17, wherein the processing of first portion of the channel layer with the neutral beam includes adjusting an angle of incidence of the neutral beam to prevent the neutral beam from reaching the second portion. of claim 17, wherein the channel layer includes an oxide semiconductor material.
